(19) United States
(12) Patent Application Publication
(10) Pub. No.: US 2021/0183894 A1
(43) Pub. Date: Jun. 17, 2021

(54) DISPLAY PANEL AND METHOD OF FABRICATING SAME

(71) Applicant: WUHAN CHINA STAR OPTOELECTRONICS SEMICONDUCTOR DISPLAY TECHNOLOGY CO., LTD., Wuhan (CN)

(72) Inventor: Ming XIANG, Wuhan (CN)

(73) Assignee: WUHAN CHINA STAR OPTOELECTRONICS SEMICONDUCTOR DISPLAY TECHNOLOGY CO. LTD., Wuhan (CN)

(21) Appl. No.: 16/349,265

(22) PCT Filed: Jan. 21, 2019
(86) PCT No.: PCT/CN2019/072501

§ 371 Date: May 12, 2019

(30) Foreign Application Priority Data
Dec. 17, 2018 (CN) 201811545474.9

(51) Int. Cl. H01L 27/12

(52) U.S. Cl. CPC H01L 27/124; H01L 27/1248

(57) ABSTRACT

A display panel and a method of fabricating the same are provided. The display panel has an active region and a non-active region. The display panel has a plurality of data lines, wherein a height difference is defined between neighboring data lines in the non-active region. The display panel can reduce an area of the non-active region by switching layers of the data lines in the non-active region.

### FIELD OF DISCLOSURE

The present disclosure relates to displays, and more particularly, to a display panel and a method of fabricating the same.

### BACKGROUND OF DISCLOSURE

As shown in FIG. 1, for a display panel having an opening of a screen, data lines 11 are arranged to bypass the opening to prevent the data lines 11 from being cut by a hole 10. However, when performing the above arrangement, it is necessary to reduce a pitch between the data lines 11 or a width of the data lines 11, resulting in generation of non-active regions (for example, at an area 14 surrounded between two dotted lines 12 and 13 in FIG. 1). However, a user's visual experience is affected.

Therefore, it is necessary to provide a display panel and a method of fabricating the same, so as to solve the problems existing in the conventional technologies.

### SUMMARY OF DISCLOSURE

From above, the present disclosure provides a display panel and a method of fabricating the same, which can reduce an area of a non-active region to improve a user's visual experience.

A main object of the present disclosure is to provide a display panel and a method of fabricating the same, which can reduce an area of the non-active region by switching layers of data lines in the non-active region.

To achieve the above object of the present disclosure, an embodiment of the present disclosure provides a display panel comprising an active region and a non-active region, wherein the display panel comprises a substrate, a first insulating layer, a first metal layer, a second insulating layer, a second metal layer, a dielectric layer, and a plurality of data lines. The first insulating layer is disposed on the substrate, wherein a buffer layer is disposed between the first insulating layer and the substrate. The first metal layer is disposed on the first insulating layer, wherein the first metal layer comprises a first gate electrode layer and a first wiring layer. The first gate electrode layer is disposed on the first insulating layer located in the active layer. The first wiring layer is disposed on the first insulating layer located in the non-active layer. The second insulating layer is disposed on the first metal layer. The second metal layer is disposed on the second insulating layer, wherein the second metal layer comprises a second gate electrode layer and a second wiring layer. The second gate electrode layer is disposed on the second insulating layer located in the active layer. The second wiring layer is disposed on the second insulating layer located in the non-active layer. The dielectric layer is disposed on the second metal layer. The plurality of data lines are disposed on the dielectric layer and comprise the plurality of data lines located in the active region and electrically connected with the first gate electrode layer; and at least two of the plurality of data lines located in the non-active region and bent in a height direction toward the first wiring layer and the second wiring layer respectively, so as to electrically connect with the first wiring layer and the second wiring layer, wherein a height difference is defined between neighboring data lines in the non-active region.

In an embodiment of the present disclosure, in the non-active region, a length of the first wiring layer is greater than a length of the second wiring layer.

To achieve the above object of the present disclosure, an embodiment of the present disclosure provides a display panel comprising an active region and a non-active region, wherein the display panel comprises a plurality of data lines, wherein a height difference is defined between neighboring data lines in the non-active region.

In an embodiment of the present disclosure, the display panel comprises a substrate, a first insulating layer, a first metal layer, a second insulating layer, a second metal layer, a dielectric layer, and the plurality of data lines. The first insulating layer is disposed on the substrate. The first metal layer is disposed on the first insulating layer, wherein the first metal layer comprises a first gate electrode layer and a first wiring layer. The first gate electrode layer is disposed on the first insulating layer located in the active layer. The first wiring layer is disposed on the first insulating layer located in the non-active layer. The second insulating layer is disposed on the first metal layer. The second metal layer is disposed on the second insulating layer, wherein the second metal layer comprises a second gate electrode layer and a second wiring layer. The second gate electrode layer is disposed on the second insulating layer located in the active layer. The second wiring layer is disposed on the second insulating layer located in the non-active layer. The dielectric layer is disposed on the second metal layer. The plurality of data lines are disposed on the dielectric layer and comprise the plurality of data lines located in the active region and electrically connected with the first gate electrode layer; and at least two of the plurality of data lines located in the non-active region and bent in a height direction toward the first wiring layer and the second wiring layer respectively, so as to electrically connect with the first wiring layer and the second wiring layer.

In an embodiment of the present disclosure, in the non-active region, a length of the first wiring layer is greater than a length of the second wiring layer.

In an embodiment of the present disclosure, the plurality of data lines comprise a first data line, a second data line, and a third data line, and the display panel comprises a substrate, an insulating layer, a first dielectric layer, the first data line, a second dielectric layer, the second data line, a third dielectric layer, and the third data line. The insulating layer is disposed on the substrate. The first dielectric layer is disposed on the insulating layer in the non-active region. The first data line is disposed on the first dielectric layer in the non-active region. The second dielectric layer is disposed on the first data line in the non-active region. The second data line is disposed on the second dielectric layer in the non-active region. The third dielectric layer is disposed on the second data line in the non-active region. The third data line is disposed on the third dielectric layer in the non-active region.

In an embodiment of the present disclosure, in the non-active region, a length of the first data line is less than a length of the second data line, and the length of the second data line is less than a length of the third data line.

In an embodiment of the present disclosure, in the non-active region, a length of the first data line is greater than a length of the second data line, and the length of the second data line is greater than a length of the third data line.

Further, another embodiment of the present disclosure provides a method of fabricating a display panel. The display panel comprises an active region and a non-active region. The method of fabricating the display panel comprises a step of forming a plurality of data lines, wherein a height difference is defined between neighboring data lines in the non-active region.

In an embodiment of the present disclosure, the method of fabricating the display panel further comprises steps of: providing a substrate; forming a first insulating layer on the substrate; forming a first metal layer on the first insulating layer, wherein the first metal layer comprises: a first gate electrode layer formed on the first insulating layer located in the active layer; and a first wiring layer formed on the first insulating layer located in the non-active layer; forming a second insulating layer on the first metal layer; forming a second metal layer on the second insulating layer, wherein the second metal layer comprises: a second gate electrode layer formed on the second insulating layer located in the active layer; and a second wiring layer formed on the second insulating layer located in the non-active layer; forming a dielectric layer on the second metal layer; and forming a plurality of data lines on the dielectric layer, wherein the plurality of data lines comprise: the plurality of data lines located in the active region and electrically connected with the first gate electrode layer; and at least two of the plurality of data lines located in the non-active region and bent in a height direction toward the first wiring layer and the second wiring layer respectively, so as to electrically connect with the first wiring layer and the second wiring layer.

In an embodiment of the present disclosure, after forming the dielectric layer and before forming the plurality of data lines, the method further comprises a step of patterning the dielectric layer and the second insulating layer, so as to form a first through hole and a second through hole, wherein at least two of the plurality of data lines are electrically connected with the first wiring layer and the second wiring layer through the first through hole and the second through hole, respectively.

In an embodiment of the present disclosure, the plurality of data lines comprise a first data line, a second data line, and a third data line, and the method of fabricating the display panel comprises: providing a substrate; forming an insulating layer on the substrate; forming a first dielectric layer on the insulating layer in the non-active region; forming the first data line on the first dielectric layer in the non-active region; forming a second dielectric layer on the first data line in the non-active region; forming the second data line on the second dielectric layer in the non-active region; forming a third dielectric layer on the second data line in the non-active region; and forming the third data line on the third dielectric layer in the non-active region.

Compared with the conventional technologies, the display panel and the method of fabricating the same of the present disclosure can reduce an area of the non-active region by switching layers of the data lines in the non-active region, so as to improve the user's visual experience.

To make the above description of the present disclosure more clearly comprehensible, it is described in detail below in examples of preferred embodiments with the accompanying drawings.

### DESCRIPTION OF DRAWINGS

FIG. 1 is a schematic diagram of data lines near an opening of a conventional display panel.

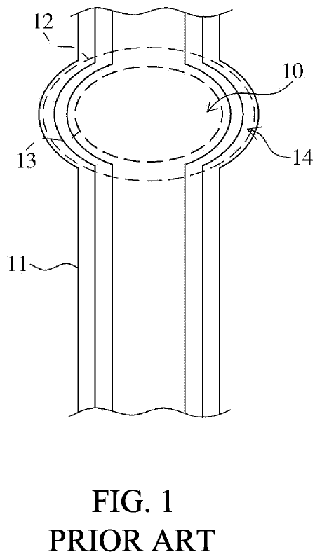

FIG. 2 is a cross-sectional schematic diagram of a display panel according to an embodiment of the present disclosure.

FIG. 3 is a cross-sectional schematic diagram of a display panel according to another embodiment of the present disclosure.

FIG. 4 is a flowchart of a method of fabricating a display panel according to an embodiment of the present disclosure.

FIG. 5 is a flowchart of a method of fabricating a display panel according to another embodiment of the present disclosure.

### DETAILED DESCRIPTION OF PREFERRED EMBODIMENTS

Following description of the various embodiments is provided to illustrate the specific embodiments of the present disclosure. Furthermore, directional terms mentioned in the present disclosure, such as upper, lower, top, bottom, front, rear, left, right, inner, outer, side, surrounding, central, horizontal, horizontal, vertical, longitudinal, axial, radial, an uppermost layer or a lowermost layer, etc., only refer to a direction of the accompanying figures. Therefore, the used directional terms are used to describe and understand the present disclosure, but the present disclosure is not limited thereto

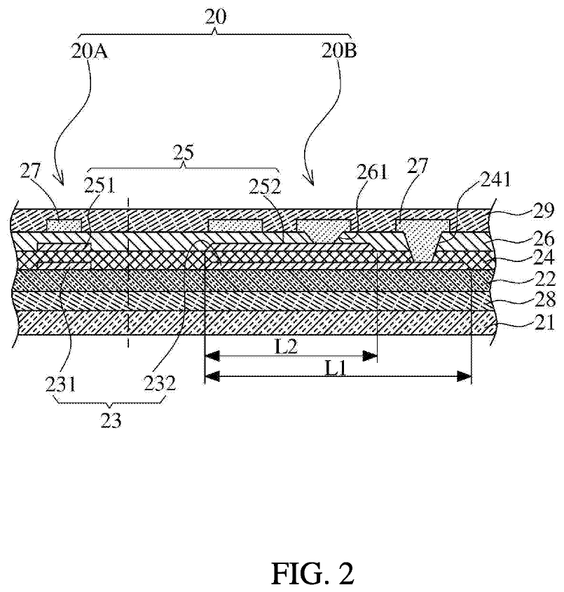

Referring to FIG. 2, a display panel 20 in an embodiment of the present disclosure is defined with an active region 20A and a non-active region 20B, where the display panel 20 comprises a substrate 21, a first insulating layer 22, a first metal layer 23, a second insulating layer 24, a second metal layer 25, a dielectric layer 26, and a plurality of data lines 27. The substrate 21 can be used to support the first insulating layer 22, the first metal layer 23, the second insulating layer 24, the second metal layer 25, the dielectric layer 26, and the plurality of data lines 27. In an embodiment, the substrate 21 is, for example, a flexible substrate or a rigid substrate. In another embodiment, the substrate 21 is, for example, a transparent substrate.

The first insulating layer 22 of the display panel 20 in an embodiment of the present disclosure is disposed on the substrate 21. In an embodiment, the first insulating layer 22 is mainly used as an insulating medium for the first metal layer 23 to be subsequently formed. In an embodiment, a buffer layer 28 can be disposed between the first insulating layer 22 and the substrate 21.

The first metal layer 23 of the display panel 20 in an embodiment of the present disclosure is disposed on the first insulating layer 22, wherein the first metal layer 23 includes a first gate layer 231 and a first wiring layer 232. The first gate layer 231 is disposed on the first insulating layer 22 in the active region 20A. The first wiring layer 232 is disposed on the first insulating layer 22 in the non-active region 20B. The first gate layer 231 is mainly used as a gate structure of a thin film transistor in the active region 20A. In general, the first gate layer 231 can be electrically connected through a scan line (not shown) to perform an on-off control of the thin film transistor. The first wiring layer 232 is substantially at the same horizontal position as the first gate layer 231, wherein the first wiring layer 232 can be simultaneously formed in a same process step of forming the first gate layer 231. The first wiring layer 232 can be electrically connected to one of the plurality of data lines 27 to achieve a layer-switching effect on the data lines 27 located in the non-active region 20B, thereby reducing an area of the non-active region 20B.

The second insulating layer 24 of the display panel 20 in an embodiment of the present disclosure is disposed on the first metal layer 23. The second insulating layer 24 can be used as an insulating medium between the first metal layer 23 and the second metal layer 25.

The second metal layer 25 of the display panel 20 in an embodiment of the present disclosure is disposed on the second insulating layer 24, wherein the second metal layer 25 includes a second gate layer 251 and a second wiring layer 252. The second gate layer 251 is disposed on the second insulating layer 24 located in the active region 20A. The second wiring layer 252 is disposed on the second insulating layer 24 located in the non-active region 20B. It is to be noted that the second gate layer 251 can form a storage capacitor with the first gate layer 231, or the second gate layer 251 can be connected to a channel region of the thin film transistor in the active region 20A to function as a bleeding voltage signal. The second wiring layer 252 and the second gate layer 251 are substantially at a same horizontal position, wherein the second wiring layer 252 can be simultaneously formed in a same process step as the second gate layer 251. The second wiring layer 252 can be electrically connected to another one of the plurality of data lines 27, so that the data lines 27 located in the non-active region 20B achieve a layer-switching effect, thereby reducing an area of the non-active region 20B. In an embodiment, in the non-active region 20B, a length L1 of the first wiring layer 232 is greater than a length L2 of the second wiring layer 252.

The dielectric layer 26 of the display panel 20 in an embodiment of the present disclosure is disposed on the second metal layer 25. The dielectric layer 26 can be used as an insulating medium between the plurality of data lines 27 and the second metal layer 25.

The plurality of data lines 27 of the display panel 20 in an embodiment of the present disclosure are disposed on the dielectric layer 26 located in the active region 20A, and the plurality of data lines 27 are respectively located in the active region 20A and the non-active region 20B, wherein the plurality of data lines 27 located in the active region 20A and electrically connected with the first gate electrode layer 231, and at least two of the plurality of data lines 27 located in the non-active region 20B and bent in a height direction toward the first wiring layer 232 and the second wiring layer 252 respectively, so as to electrically connect with the first wiring layer 232 and the second wiring layer 252. In an embodiment, a planarization layer 29 can be disposed on the plurality of data lines 27.

In an embodiment, after forming the dielectric layer 26 and before forming the plurality of data lines 27, a patterning process can be performed on the dielectric layer 26 and the second insulating layer 24, so as to form a first through hole 261 and a second through hole 241, wherein at least two of the plurality of data lines 27 are electrically connected with the first wiring layer 232 and the second wiring layer 252 through the first through hole 261 and the second through hole 241, respectively.

It should be noted that in the display panel 20 in an embodiment of the present disclosure, a layer-switching process is performed on the data lines 27 located in the non-active region 20B (for example, in the present embodiment, the data lines 27 are switched to the first wiring layer 232 or the second wiring layer 252). It can be seen that there is a height difference between adjacent ones of the plurality of data lines 27 in the non-active region 20B, wherein the height difference is provided, for example, by a thickness of the second insulating layer 24 or a thickness of the dielectric layer 26. By such a layer-switching process, under a premise of maintaining a spacing between the adjacent data lines (in the present embodiment, the height difference can be regarded as the spacing) or a width of the data lines, the display panel 20 in an embodiment of the present disclosure can be completed. Therefore, the area of the non-active region 20B can be reduced. According to an actual measurement, as shown in FIG. 2, the display panel 20 in an embodiment of the present disclosure has an area of the non-active region 20B which is substantially reduced to one-third of an original area of a conventional non-active region because three data lines 27 are arranged in a vertical direction.

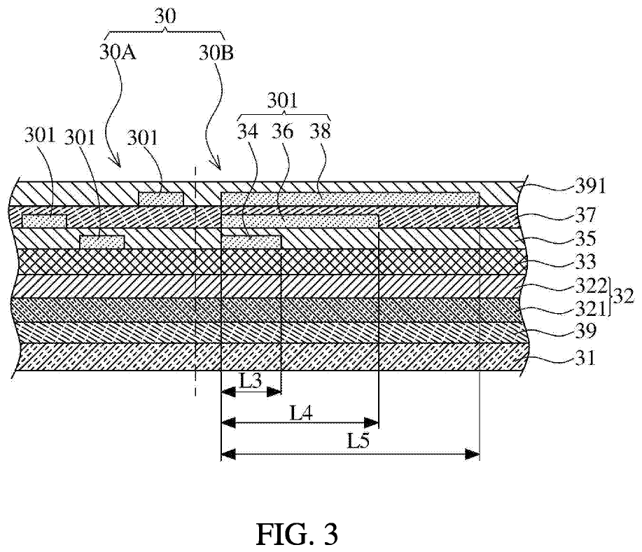

Referring to FIG. 3, a display panel 30 according to an embodiment of the present disclosure is defined with an active region 30A and a non-active region 30B. The display panel 30 includes a plurality of data lines 301, a substrate 31, an insulating layer 32, a first dielectric layer 33, a second dielectric layer 35, and a third dielectric layer 37. The data lines 301 include a first data line 34, a second data line 36, and a third data line 38. The substrate 30 can be used to support the insulating layer 32, the first dielectric layer 33, the first data line 34, the second dielectric layer 35, the second data line 36, the third dielectric layer 37, and the third data line 38. In an embodiment, the substrate 31 is, for example, a flexible substrate or a rigid substrate. In another embodiment, the substrate 31 is, for example, a transparent substrate.

The insulating layer 32 of the display panel 30 in an embodiment of the present disclosure is disposed on the substrate 31. In an embodiment, the insulating layer 32 is used as a gate insulating layer (a gate structure not being shown). In an embodiment, a buffer layer 39 can be disposed between the insulating layer 32 and the substrate 31. In another embodiment, the insulating layer 32 can be a two-layered structure, for example, including a first gate insulating layer 321 and a second gate insulating layer 322, respectively, used for an insulating layer with two gate structures.

The first dielectric layer 33 of the display panel 30 in an embodiment of the present disclosure is disposed on the insulating layer 32 in the non-active region 30B. In an embodiment, the first dielectric layer 33 can be formed on the insulating layer 32 by a general semiconductor process.

The first data line 34 of the display panel 30 in an embodiment of the present disclosure is disposed on the first dielectric layer 33 in the non-active region 30B. In an embodiment, the first data line 34 can be formed on the first dielectric layer 33 by a deposition process of a general semiconductor process.

The second dielectric layer 35 of the display panel 30 in an embodiment of the present disclosure is disposed on the first data line 34 in the non-active region 30B. In an embodiment, the second dielectric layer 35 can be formed on the first data line 34 by a deposition process of a general semiconductor process.

The second data line 36 of the display panel 30 in an embodiment of the present disclosure is disposed on the second dielectric layer 35 in the non-active region 30B. In an embodiment, the second data line 36 can be formed on the second dielectric layer 35 by a deposition process of a general semiconductor process.

The third dielectric layer 37 of the display panel 30 in an embodiment of the present disclosure is disposed on the second data line 36 in the non-active region 30B. In an embodiment, the third dielectric layer 37 can be formed on the second data line 36 by a deposition process of a general semiconductor process.

The third data line 38 of the display panel 30 in an embodiment of the present disclosure is disposed on the third dielectric layer 37 in the non-active region 30B. In an embodiment, the third data line 38 can be formed on the third dielectric layer 37 by deposition in a general semiconductor process. In an embodiment, a planarization layer 391 can be disposed on the third data line 38.

It should be noted that in the display panel 30 in an embodiment of the present disclosure, a layer-switching process is performed by arranging the plurality of data lines 301 located in the non-active region 30B. For example, in the embodiment, the first data line 34, the second data line 36, and the third data line 38 in the non-active region 30B are disposed on layered structures with different heights (i.e., adjacent ones of the plurality of data lines 301 in the non-active region 30B have a height difference). By such a layer-switching process, under a premise of maintaining a spacing between the adjacent data lines (in the present embodiment, the height difference can be regarded as the spacing) or a width of the data lines, the display panel 30 in an embodiment of the present disclosure can be completed. Therefore, the area of the non-active region 30B can be reduced. According to an actual measurement, as shown in FIG. 3, the display panel 30 in an embodiment of the present disclosure has an area of the non-active region 30B which is substantially reduced to three-thirds of an original area of a conventional non-active region because the first data line 34, the second data line 36, and the third data line 38 are arranged in a vertical direction.

In an embodiment, in the non-active region 30B, a length L3 of the first data line 34 is less than a length L4 of the second data line 36, and the length L4 of the second data line 36 is less than a length L5 of the third data line 38. In another embodiment, in the non-active region 30B, a length of the first data line 34 is greater than a length of the second data line 36, and the length of the second data line 36 is greater than a length of the data line 38.

It is to be noted that the plurality of data lines 301 introduced in the above embodiment can be simultaneously positioned in the active region 30A and the non-active region 30B. Specifically, the plurality of data lines 301 located in the active region 30A can be used to electrically connect drain electrodes (not shown) of the thin film transistors of the display panel 30, and the plurality of data lines 301 located in the non-active region 30B reduce the area of the non-active region 30B by a layer-switching process as described above. In an embodiment, the data lines 301 located in the active region 30A can be disposed to locate on the first dielectric layer 33 of the active region 30A, on the second dielectric layer 35 of the active region 30A, or on the third dielectric layer 37 of the active region 30A, according to a design.

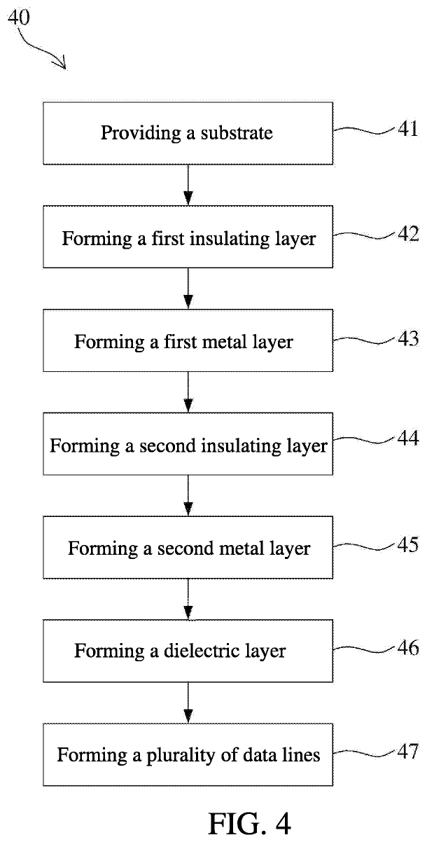

Referring to FIG. 4, another embodiment of the present disclosure provides a method 40 of fabricating a display panel. The display panel comprises an active region and a non-active region. The method of fabricating the display panel comprises steps 41 to 47: providing a substrate (step 41); forming a first insulating layer on the substrate (step 42); forming a first metal layer on the first insulating layer, wherein the first metal layer comprises: a first gate electrode layer formed on the first insulating layer located in the active layer; and a first wiring layer formed on the first insulating layer located in the non-active layer (step 43); forming a second insulating layer on the first metal layer (step 44); forming a second metal layer on the second insulating layer, wherein the second metal layer comprises: a second gate electrode layer formed on the second insulating layer located in the active layer; and a second wiring layer formed on the second insulating layer located in the non-active layer (step 45); forming a dielectric layer on the second metal layer (step 46); and forming a plurality of data lines on the dielectric layer, wherein the plurality of data lines comprise: the plurality of data lines located in the active region and electrically connected with the first gate electrode layer; and at least two of the plurality of data lines located in the non-active region and bent in a height direction toward the first wiring layer and the second wiring layer respectively, so as to electrically connect with the first wiring layer and the second wiring layer (step 47).

In an embodiment, various layered structures formed in steps 42 to 47 can be formed by, for example, methods used in general semiconductor processes (e.g., by depositing, sputtering, etc.).

In an embodiment, after forming the dielectric layer and before forming the plurality of data lines, the method further comprises a step of patterning the dielectric layer and the second insulating layer, so as to form a first through hole and a second through hole, wherein at least two of the plurality of data lines are electrically connected with the first wiring layer and the second wiring layer through the first through hole and the second through hole, respectively.

In an embodiment, the display panel 20 in an embodiment of the present disclosure can be fabricated by the method 40 of fabricating the display panel.

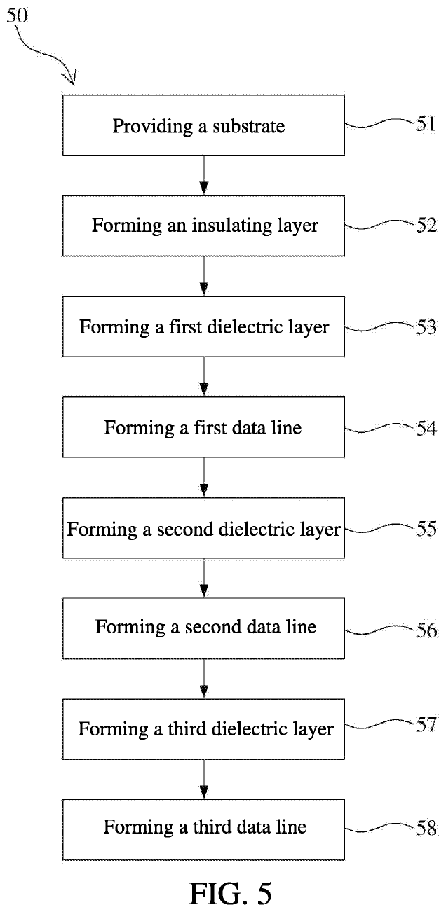

Referring to FIG. 5, a further embodiment of the present disclosure provides a method 50 of fabricating a display panel. The display panel comprises an active region and a non-active region. The method 50 of fabricating the display panel comprises steps 51 to 58: providing a substrate (step 51); forming an insulating layer on the substrate (step 52); forming a first dielectric layer on the insulating layer in the non-active region (step 53); forming the first data line on the first dielectric layer in the non-active region (step 54); forming a second dielectric layer on the first data line in the non-active region (step 55); forming the second data line on the second dielectric layer in the non-active region (step 56); forming a third dielectric layer on the second data line in the non-active region (step 57); and forming the third data line on the third dielectric layer in the non-active region (step 58).

In an embodiment, various layered structures formed in steps 52 to 58 can be formed by, for example, methods used in general semiconductor processes (e.g., by depositing, sputtering, etc.).

In an embodiment, the display panel 30 in an embodiment of the present disclosure can be fabricated by the method 50 of fabricating the display panel.

From above, the display panel and the method of fabricating the same of the present disclosure can reduce an area of the non-active region by switching layers of the data lines in the non-active region, so as to improve users' visual experience.

The present disclosure has been described in relative embodiments described above, but the above embodiments are merely examples for implementing the present disclosure. It is noted that the disclosed embodiments do not limit the scope of the disclosure. On the contrary, modifications and equal settings included in the spirit and scope of the claims are all included in the scope of the present disclosure.

1. A display panel, comprising an active region and a non-active region, the display panel comprising:
a substrate;
a first insulating layer disposed on the substrate, wherein a buffer layer is disposed between the first insulating layer and the substrate;
a first metal layer disposed on the first insulating layer, wherein the first metal layer comprises:
a first gate electrode layer disposed on the first insulating layer located in the active region; and
a first wiring layer disposed on the first insulating layer located in the non-active region;
a second insulating layer disposed on the first metal layer;
a second metal layer disposed on the second insulating layer, wherein the second metal layer comprises:
a second gate electrode layer disposed on the second insulating layer located in the active layer; and
a second wiring layer disposed on the second insulating layer located in the non-active layer;
a dielectric layer disposed on the second metal layer; and
a plurality of data lines disposed on the dielectric layer and comprising:
the plurality of data lines located in the active region and electrically connected with the first gate electrode layer; and
at least two of the plurality of data lines located in the non-active region and bent in a height direction toward the first wiring layer and the second wiring layer respectively, so as to electrically connect with the first wiring layer and the second wiring layer, wherein a height difference is defined between neighboring data lines in the non-active region.

2. The display panel according to claim 1, wherein in the non-active region, a length of the first wiring layer is greater than a length of the second wiring layer.

3. A display panel, comprising an active region and a non-active region, the display panel comprising a plurality of data lines, wherein a height difference is defined between neighboring data lines in the non-active region.

4. The display panel according to claim 3, comprising:
a substrate;
a first insulating layer disposed on the substrate;
a first metal layer disposed on the first insulating layer, wherein the first metal layer comprises:
a first gate electrode layer disposed on the first insulating layer located in the active region; and
a first wiring layer disposed on the first insulating layer located in the non-active region;
a second insulating layer disposed on the first metal layer;
a second metal layer disposed on the second insulating layer, wherein the second metal layer comprises:
a second gate electrode layer disposed on the second insulating layer located in the active region; and
a second wiring layer disposed on the second insulating layer located in the non-active region;
a dielectric layer disposed on the second metal layer; and
a plurality of data lines disposed on the dielectric layer and comprising:
the plurality of data lines located in the active region and electrically connected with the first gate electrode layer; and
at least two of the plurality of data lines located in the non-active region and bent in a height direction toward the first wiring layer and the second wiring layer respectively, so as to electrically connect with the first wiring layer and the second wiring layer.

5. The display panel according to claim 4, wherein in the non-active region, a length of the first wiring layer is greater than a length of the second wiring layer.

6. The display panel according to claim 3, wherein the plurality of data lines comprise a first data line, a second data line, and a third data line, and the display panel comprises:
a substrate;
an insulating layer disposed on the substrate;
a first dielectric layer disposed on the insulating layer in the non-active region;
the first data line disposed on the first dielectric layer in the non-active region;
a second dielectric layer disposed on the first data line in the non-active region;
the second data line disposed on the second dielectric layer in the non-active region;
a third dielectric layer disposed on the second data line in the non-active region; and
the third data line disposed on the third dielectric layer in the non-active region.

7. The display panel according to claim 6, wherein in the non-active region, a length of the first data line is less than a length of the second data line, and the length of the second data line is less than a length of the third data line.

8. The display panel according to claim 6, wherein in the non-active region, a length of the first data line is greater than a length of the second data line, and the length of the second data line is greater than a length of the third data line.

9. A method of fabricating a display panel, the display panel comprising an active region and a non-active region, the method of fabricating the display panel comprising a step of forming a plurality of data lines, wherein a height difference is defined between neighboring data lines in the non-active region.

10. The method of fabricating the display panel according to claim 9, further comprising steps of:
providing a substrate;
forming a first insulating layer on the substrate;
forming a first metal layer on the first insulating layer, wherein the first metal layer comprises:
a first gate electrode layer formed on the first insulating layer located in the active region; and
a first wiring layer formed on the first insulating layer located in the non-active region;
forming a second insulating layer on the first metal layer;
forming a second metal layer on the second insulating layer, wherein the second metal layer comprises:
a second gate electrode layer formed on the second insulating layer located in the active region; and
a second wiring layer formed on the second insulating layer located in the non-active region;
forming a dielectric layer on the second metal layer; and
forming a plurality of data lines on the dielectric layer, wherein the plurality of data lines comprise:
the plurality of data lines located in the active region and electrically connected with the first gate electrode layer; and
at least two of the plurality of data lines located in the non-active region and bent in a height direction toward the first wiring layer and the second wiring layer respectively, so as to electrically connect with the first wiring layer and the second wiring layer.

11. The method of fabricating the display panel according to claim 10, wherein after forming the dielectric layer and before forming the plurality of data lines, the method further comprises a step of patterning the dielectric layer and the second insulating layer, so as to form a first through hole and a second through hole, wherein at least two of the plurality of data lines are electrically connected with the first wiring layer and the second wiring layer through the first through hole and the second through hole, respectively.

12. The method of fabricating the display panel according to claim 9, wherein the plurality of data lines comprise a first data line, a second data line, and a third data line, and the method of fabricating the display panel comprises:
providing a substrate;
forming an insulating layer on the substrate;
forming a first dielectric layer on the insulating layer in the non-active region;
forming the first data line on the first dielectric layer in the non-active region;
forming a second dielectric layer on the first data line in the non-active region;
forming the second data line on the second dielectric layer in the non-active region;
forming a third dielectric layer on the second data line in the non-active region; and
forming the third data line on the third dielectric layer in the non-active region.
